(19) United States
(12) Patent Application Publication
(10) Pub. No.: US 2026/0282679 A1
(43) Pub. Date: Sep. 17, 2026

(54) CIRCUIT BOARD AND DISPLAY DEVICE PROVIDED WITH SAME

(71) Applicant: Sharp Display Technology Corporation, Kameyama City, Mie (JP)

(72) Inventors: Masahito SANO, Kameyama City (JP); Kazuatsu ITO, Kameyama City (JP); Mehadi AMAN, Kameyama City (JP)

(21) Appl. No.: 19/473,218

(22) PCT Filed: Apr. 10, 2023
(86) PCT No.: PCT/JP2023/014545

§ 371 Date: Oct. 7, 2025

(51) Int. Cl. H10K 59/131; H05K 1/03; H05K 1/09; H05K 1/11; H10K 59/95

(52) U.S. Cl. CPC H10K 59/131; H05K 1/0393; H05K 1/09; H05K 1/115; H05K 1/118; H10K 59/95; H05K 2201/0338; H05K 2201/10128; H05K 2201/10166

(57) ABSTRACT

A circuit board includes the following: a base coat film provided on a substrate layer; a first semiconductor layer provided on the base coat film; a stacked insulating film provided so as to cover the first semiconductor layer; and a second semiconductor layer provided on the stacked insulating film and containing an oxide semiconductor. The stacked insulating film includes a contact hole penetrating to the first semiconductor layer. The second semiconductor layer is electrically connected to the first semiconductor layer via the contact hole. The circuit board further includes an island-shaped intervening layer interposed between the substrate layer and the first semiconductor layer in a region corresponding to the contact hole.

### TECHNICAL FIELD

The present disclosure relates to a circuit board and a display device provided with the same.

### BACKGROUND ART

Various display devices, such as liquid crystal displays and organic electroluminescence (hereinafter, also referred to as EL) displays, are provided with a circuit board called a backplane. The circuit board includes a plurality of thin-film transistors (hereinafter, referred to as TFTs) mounted on a substrate. Each TFT is connected to wiring lines and electrodes provided below or above, and/or to a semiconductor layer constituting another TFT.

The circuit board includes a base coat film provided on the substrate. On the base coat film is a first TFT, and conductive portions, such as wiring lines, electrodes, and semiconductor layers. These conductive portions are covered with an insulating film. On the insulating film is a second TFT. The semiconductor layer constituting the second TFT is connected to the conductive portion via a contact hole formed in the insulating film. International Publication No. 2020/217477 discloses an example circuit board having such a configuration.

### SUMMARY

### Technical Problem

The foregoing circuit board is susceptible to external moisture intrusion from the circuit board's end face through the interface between the substrate and base coat film. The moisture propagated through the interface between the substrate and base coat film transmits through the base coat film and semiconductor layer directly under the insulating film's contact holes and then intrudes into the insulating film's upper part via the contact holes. When the semiconductor layer constituting the upper TFT contains an oxide semiconductor, the moisture intruded into the insulating film's upper part and then reached the semiconductor layer changes the semiconductor layer's property.

It is an object of the present disclosure to prevent the property of a semiconductor layer containing an oxide semiconductor from a change resulting from moisture intrusion.

### Solution to Problem

The technique of the present disclosure is directed to a circuit board. The circuit board according to the technique of the present disclosure includes the following: a substrate; a base coat film provided on the substrate; a conductive portion provided on the base coat film; an insulating film provided so as to cover the conductive portion; and a semiconductor layer provided on the insulating film and containing an oxide semiconductor. The insulating film includes a contact hole penetrating to the conductive portion. The semiconductor layer is electrically connected to the conductive portion via the contact hole. The circuit board further includes an intervening layer having an island shape, and interposed between the substrate and the conductive portion in a region corresponding to the contact hole.

### Advantageous Effect of Disclosure

The technique of the present disclosure can prevent the property of a semiconductor layer containing an oxide semiconductor from a change resulting from moisture intrusion.

### BRIEF DESCRIPTION OF DRAWINGS

FIG. 1 is a plan view of an example schematic configuration of an organic EL display according to a first embodiment.

FIG. 2 is a cross-sectional view of the organic EL display taken along line II-II in FIG. 1.

FIG. 3 is a plan view of example pixels and example various wiring lines constituting the display region of the organic EL display according to the first embodiment.

FIG. 4 is a cross-sectional view of the organic EL display taken along line IV-IV in FIG. 3.

FIG. 5 is a plan view of example main components of the organic EL display according to the first embodiment.

FIG. 6 is a cross-sectional view of the organic EL display taken along line VI-VI in FIG. 5.

FIG. 7 is a plan view of an example schematic configuration of an organic EL display according to a second embodiment.

FIG. 8 is a cross-sectional view of an example peripheral region (upper part) corresponding to FIG. 6 and an example inner region (lower part) corresponding to FIG. 6, in the display region of the organic EL display according to the second embodiment.

FIG. 9 is a plan view of an example schematic configuration of an organic EL display according to a third embodiment.

FIG. 10 is a cross-sectional view of an example peripheral region (upper part) corresponding to FIG. 6, an example middle region (middle part) corresponding to FIG. 6, and an example inner region (lower part) corresponding to FIG. 6, in the display region of the organic EL display according to the third embodiment.

FIG. 11 is a cross-sectional view of an organic EL display according to a modification corresponding to FIG. 6.

FIG. 12 is a cross-sectional view of an organic EL display according to a modification corresponding to FIG. 6.

FIG. 13 is a cross-sectional view of an organic EL display according to a modification corresponding to FIG. 6.

FIG. 14 is a cross-sectional view of an organic EL display according to another embodiment corresponding to FIG. 4.

FIG. 15 is a cross-sectional view of an organic EL display according to a comparative example corresponding to FIG. 6.

FIG. 16 is a cross-sectional view of the organic EL display according to the comparative example corresponding to FIG. 6.

### DESCRIPTION OF EMBODIMENTS

Example embodiments will be detailed with reference to the drawings. The following embodiments will describe organic EL displays by way of example, as a display device according to the present disclosure. It is noted that the drawings are presented for conceptually describing the technique of the present disclosure. Thus, some of the drawings illustrate dimensions, ratios, or numbers in an exaggerated or simplified manner in order to facilitate the understanding of the technique of the present disclosure.

In the following embodiments, a “first direction” means the lateral direction of the display device's screen during a predetermined use. A “second direction” is a direction orthogonal to the first direction and means the longitudinal direction of the display device's screen during the predetermined use. A row of components, such as subpixels, means a lateral arrangement of a plurality of components forming a line in the first direction. A column of components, such as subpixels, means a longitudinal arrangement of a plurality of components forming a line in the second direction.

In the following embodiments, that one component, such as a film, a layer, or an element, is provided or formed above another component, such as a film, a layer, or an element, means not only an instance where the component is directly above the other component, but also an instance where a different component, such as a film, a layer, or and an element, is interposed between the foregoing components.

In the following embodiments, that one component is connected to another component means their electrical connection unless otherwise specified. This description means not only their direct connection, but also their indirect connection with the intervention of a different component, within a scope not departing from the spirit of the technique of the present disclosure. The description also includes an instance where one component is integrated with another component, that is, a part of one component constitutes another component.

In the following embodiments, that one component is in the same layer as another component means that the component is formed in the same process as the other component. That one component is below another component means that the component is formed in a process step anterior to a process step of forming the other component, or that the component is formed from a film formed in the anterior process step. That one component is above another component means that the component is formed in a process step posterior to a process step of forming the other component, or that the component is formed from a film formed in the posterior process step.

In the following embodiments, that one component is identical or equivalent to another component means not only an instance where the component and the other component are exactly identical or exactly equivalent, but also an instance where the component and the other component are substantially identical or substantially equivalent; they may be different due to manufacture variations or within the range of a tolerance.

In the following embodiments, first, second, and third . . . are used to distinguish words provided with these ordinal numbers and are not intended to limit the number of words and even the order of the words of some kind.

### First Embodiment

An organic EL display 1 according to a first embodiment is used for the displays of mobile equipment, such as multi-function phones called smartphones, and tablet terminals. The organic EL display 1 may be used for the displays of other various kinds of equipment, including a personal computer (PC) and a television set.

### Configuration of Organic EL Display

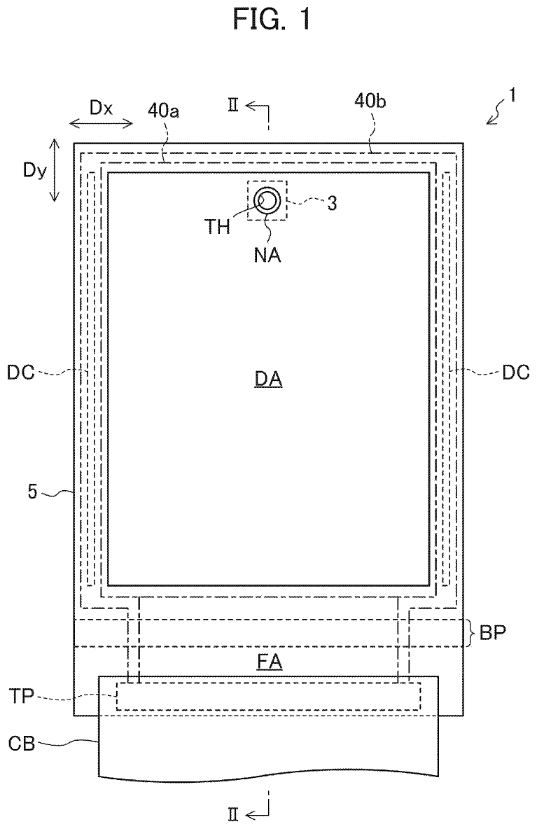

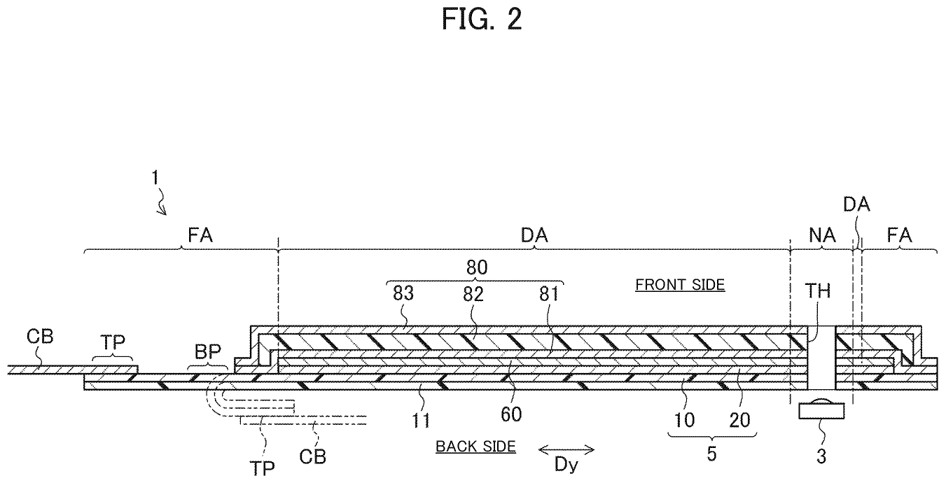

As illustrated in FIGS. 1 and 2, the organic EL display 1 constitutes, in combination with a camera 3, a display device equipped with a front-facing camera that can capture the screen front side by using the camera 3. The organic EL display 1 adopts an active-matrix driving scheme and is configured to perform full color display. The organic EL display 1 has a display region DA, a frame region FA, and a non-display region NA.

The display region DA is a region for displaying an image and constitutes a screen. The display region DA is formed in a rectangular shape for example. The display region DA may have a substantially rectangular shape, including a shape having at least one arc-shaped side, a shape having at least one arc-shaped corner, and a shape having at least one notched side; alternatively, the display region DA may have any other given shape.

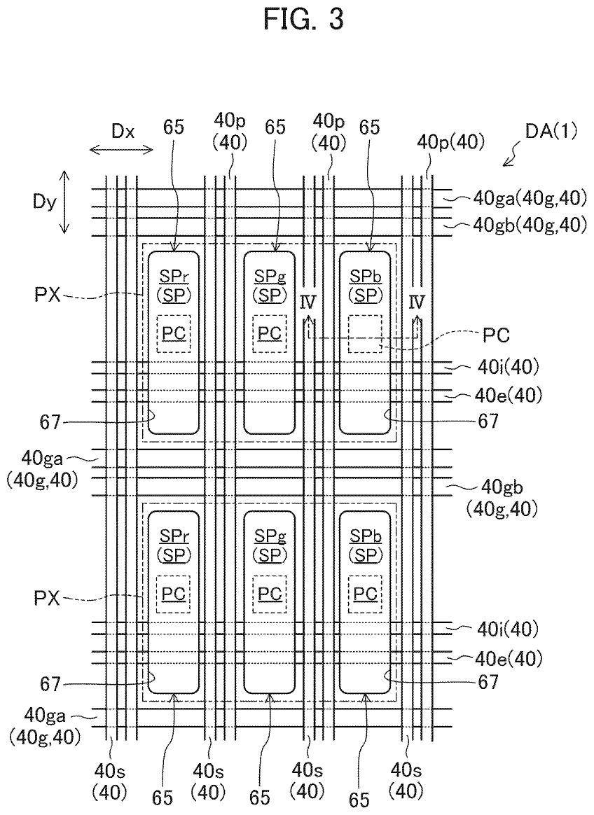

As illustrated in FIG. 3, the display region DA includes a plurality of pixels PX. The plurality of pixels PX is arranged in matrix. Each pixel PX includes three subpixels SP. The three subpixels SP are a subpixel SPr that emits red light, a subpixel SPg that emits green light, and a subpixel SPb that emits blue light. These three subpixels SPr, SPg, and SPb are arranged in a stripe manner for example.

The display region DA includes a plurality of organic EL elements 65 and a plurality of pixel circuits PC. The plurality of organic EL elements 65 is provided in correspondence with the plurality of subpixels SP. Each subpixel SP includes a corresponding one of the organic EL elements 65. The pixel circuits PC are each a circuit per subpixel and each control the emission of the organic EL element 65 constituting a corresponding one of the subpixels SP.

As illustrated in FIGS. 1 and 2, the frame region FA is a region constituting a non-display part outside the screen. The frame region FA is formed in the form of, for instance, a rectangular frame around the display region DA. The frame region FA may have a frame shape other than a rectangular shape. The frame region FA includes a terminal section TP and a bending section BP.

The terminal section TP is a section for connection to external circuits, such as a display control circuit (source driver). The terminal section TP is provided near the outer edge of a portion constituting one side of the frame region FA extending in a first direction Dx, so as to extend along the one side. Although not shown, the terminal section TP has a plurality of terminals. The terminal section TP is connected to a wiring board CB, such as a flexible printed circuit (FPC).

The bending section BP is provided between the terminal section TP and the display region DA, and extends laterally all across the frame region FA in the first direction. The frame region FA is bent at, for instance, 180 degrees so as to form a U-shape at the bending section BP (denoted by a dash-dot-dot-dash line in FIG. 2). Accordingly, the terminal section TP is disposed on the backside of the organic EL display 1.

In the frame region FA is driver circuits DC. The driver circuits DC are disposed in portions of the frame region FA constituting sides (the right and left sides in FIG. 1) adjacent to the side on which the terminal section TP is provided. The driver circuits DC are formed monolithically as a part of a TFT layer 20, which will be described later on. The driver circuits DC include a gate driver and an emission driver.

The frame region FA also includes a first frame line 40a and a second frame line 40b. The first frame line 40a and the second frame line 40b are both power supply trunks and formed around the display region DA to extend the terminal section TP. The first frame line 40a is supplied with high-level power supply voltage (ELVDD) via the wiring board CB. The second frame line 40b is supplied with low-level power supply voltage (ELVSS) via the wiring board CB.

The non-display region NA is a region constituting a non-display part within the screen. The non-display region NA is formed in the form of, for instance, a circular island inside the display region DA. The non-display region NA may be provided so as to be continuous to the frame region FA. Further, the non-display region NA may have a shape other than a circular shape. The non-display region NA includes a through-hole TH. The through-hole TH penetrates in the thickness direction of a circuit board 5, which will be described later on, and allows light to pass from the front to back of the organic EL display 1.

The light passed through the through-hole TH is used for imaging with the camera 3. The camera 3 is disposed in correspondence with the through-hole TH on the backside of the organic EL display 1. The camera 3 is an example electronic component that uses light. The camera 3 has an image sensor, such as a charged coupled device (CCD) and/or a complementary metal oxide semiconductor (CMOS). The camera 3 is disposed inside a casing (not shown) accommodating the organic EL display 1.

### Stacked Structure of Organic EL Display

As illustrated in FIG. 2, the organic EL display 1 includes the circuit board 5, a light-emitting element layer 60, and a sealing film 80. The circuit board 5 includes a substrate layer 10 and the thin-film transistor layer (TFT layer) 20.

### Substrate Layer

The substrate layer 10 is an example substrate constituting the base of the organic EL display 1. The substrate layer 10 in this example is a flexible resin substrate. The substrate layer 10 is formed from an organic resin material, such as polyimide resin, polyamide resin, or epoxy resin. The substrate layer 10 may have a stack of an organic insulating film containing such an organic resin material as described above, and an inorganic insulating film of silicon oxide (SiO₂) or other materials. The substrate layer 10 has a backside on which a light-transparent (which mean being transparent to visible light in this example) protective film 11 is attached.

### TFT Layer

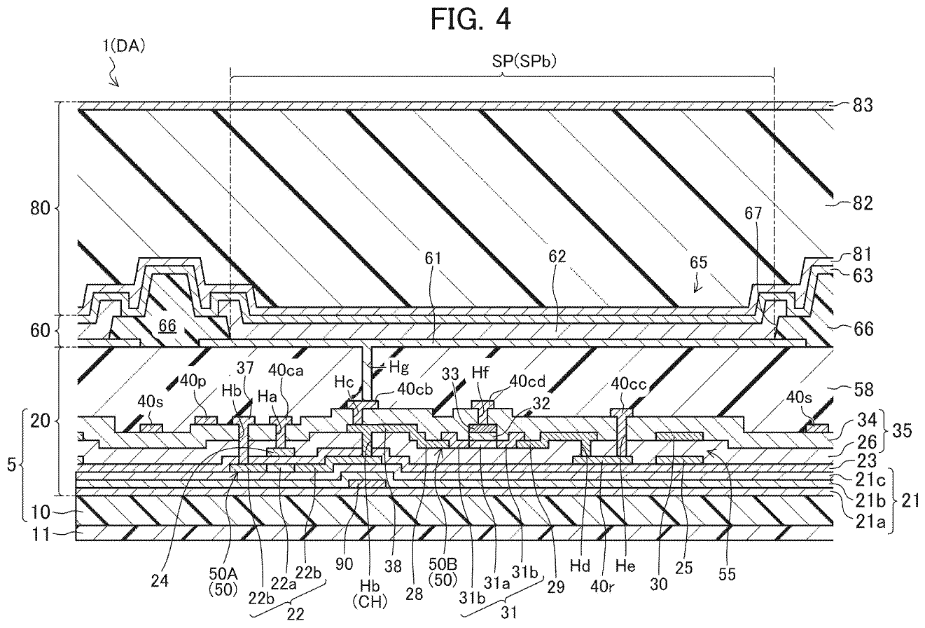

The TFT layer 20 is provided on the substrate layer 10. The TFT layer 20 includes a base coat film 21, which is illustrated in FIGS. 3 and 4, various wiring lines 40, and a plurality of pixel circuits PC as well as the foregoing driver circuits DC. The driver circuits DC, the various wiring lines 40, and the pixel circuits PC are provided on the base coat film 21. The base coat film 21 is provided on the substrate layer 10 so as to extend substantially all over the surface of the substrate layer 10. The base coat film 21 is formed by stacking a plurality of inorganic insulating films.

The base coat film 21 in this example has a three-ply structure. To be specific, the base coat film 21 has a stack of, in sequence, a first inorganic insulating film 21a, a second inorganic insulating film 21b, and a third inorganic insulating film 21c. Each of the first inorganic insulating film 21a and third inorganic insulating film 21c contains silicon oxide (SiO₂) for instance. The second inorganic insulating film 21b contains silicon nitride (SiN) for instance. The second inorganic insulating film 21b in this case may be thinner than each of the first inorganic insulating film 21a and third inorganic insulating film 21c.

The various wiring lines 40 include the foregoing first frame line 40a and the second frame line 40b. Other than these, the various wiring lines 40 include a plurality of gate lines 40g, a plurality of emission control lines 40e, a plurality of initialization lines 40i, a plurality of power supply lines 40p, and a plurality of source lines 40s. These gate lines 40g, emission control lines 40e, initialization lines 40i, power supply lines 40p, and source lines 40s are all provided in the display region DA.

The plurality of gate lines 40g is each a wiring line for transmitting a gate signal to the pixel circuits PC. The plurality of gate lines 40g is arranged at intervals in a second direction Dy and extends in parallel with each other in the first direction Dx. The gate lines 40g include first gate lines 40ga and second gate lines 40gb.

The first gate lines 40ga are the gate lines 40g for use in controlling P-channel TFTs 50. The second gate lines 40gb are the gate lines 40g for use in controlling N-channel TFTs 50. The first gate lines 40ga and the second gate lines 40gb are provided for each row of the subpixels SP. Each first gate line 40ga and each second gate line 40gb are routed to the frame region FA to be connected to the gate driver of the driver circuit DC.

The plurality of emission control lines 40e is each a wiring line for transmitting an emission signal to the pixel circuits PC. The plurality of emission control lines 40e is arranged at intervals in the second direction Dy and extends in parallel with each other in the first direction Dx. The emission control line 40e is provided for each row of the subpixels SP. Each emission control line 40e is routed to the frame region FA to be connected to the emission driver of the driver circuit DC.

The plurality of initialization lines 40g is wiring lines for applying an initialization voltage to the pixel circuits PC. The plurality of initialization lines 40i is arranged at intervals in the second direction Dy and extends in parallel with each other in the first direction Dx. The initialization line 40i is provided for each row of the subpixels SP. Each initialization line 40e is routed to the frame region FA to be connected to the driver circuit DC or second frame line 40b.

The plurality of power supply line 40p is each a wiring line for applying a predetermined high-level power supply voltage (ELVDD) to the pixel circuit PC. The plurality of power supply lines 40p is arranged at intervals in the first direction Dx and extends in parallel with each other in the second direction Dy. The power supply line 40p is provided for each column of the subpixels SP. Each power supply line 40p is routed to the frame region FA to be connected to the first frame line 40a.

The plurality of source lines 40s is each a wiring line for transmitting a source signal to the pixel circuit PC. The plurality of source line 40s is arranged at intervals in the first direction Dx and extends in parallel with each other in the second direction Dy. The source line 40s is provided for each column of the subpixels SP. Each source line 40s is routed to the terminal section TP to be connected to a display control circuit (source driver) via the wiring board CB.

The first gate lines 40ga, the emission control lines 40e, and the initialization lines 40i are formed in the same layer using the same material as first gate electrodes 24, first capacitive electrodes 25, and relay lines 40r, all of which will be described later on. The second gate lines 40gb are formed in the same layer using the same material as a second gate electrode, which will be described later on. The power supply lines 40p and the source lines 40s are formed in the same layer using the same material as a first terminal electrode 37, a second terminal electrode 38, and first to fourth connection lines 40ca, 40cb, 40cc and 40cd, all of which will be described later on.

Each pixel circuit PC is connected to the first gate line 40ga, the second gate line 40gb, the initialization line 40i, the emission control line 40e, and the power supply line 40p. Each pixel circuit PC operates based on the signals and voltages supplied from these various wiring lines 40, and in each frame, the pixel circuit PC resets electric charges accumulated in a pixel electrode 61 and then supplies a driving current corresponding to the source signal to the organic EL element 65.

The pixel circuit PC includes a plurality of TFTs 50 and a capacitor 55. The plurality of TFTs 50 constituting the pixel circuit PC includes first TFTs 50A and second TFTs 50B. The first TFT 50A and the second TFT 50B are provided along with the capacitor 55 in correspondence with the plurality of subpixels SP to constitute the pixel circuit PC for each subpixel SP. For instance, a plurality of first TFTs 50A and a plurality of second TFTs 50B are included in the pixel circuit PC.

The first TFTs 50A are formed as top-gate TFTs having a top-contact structure. The first TFTs 50A each have a first semiconductor layer 22, a first gate insulating film 23, a first gate electrode 24, an interlayer insulating film 35, the first terminal electrode 37, and the second terminal electrode 38.

The first semiconductor layer 22 is provided in the form of an island on the base coat film 21 and separated individually for each first TFT 50A. The first semiconductor layer 22 may be formed in continuity in the plurality of first TFTs 50A. The first semiconductor layer 22 includes a channel region 22a and a pair of conductor regions 22b. The channel region 22a is provided between the pair of conductor regions 22b. The pair of conductor regions 22b is spaced from each other with the channel region 22a interposed therebetween. The pair of conductor regions 22b, which is a part of the first semiconductor layer 22, is example conductive portions.

The first gate insulating film 23 covers a plurality of first semiconductor layers 22 and is provided in continuity in the plurality of first TFTs 50A. The first gate insulating film 23 may be provided in the form of an island on each first semiconductor layer 22 and separated individually for each first TFT 50A. The first gate electrode 24 is provided on the first gate insulating film 23. The first gate electrode 24 overlaps the channel region 22a of the first semiconductor layer 22 via the first gate insulating film 23.

The interlayer insulating film 35 has a stack of, in sequence, a first interlayer insulating film 26 and a second interlayer insulating film 34 on the first gate insulating film 23. The interlayer insulating film 35 is provided so as to cover a plurality of first gate electrodes 24. The interlayer insulating film 35 includes a first contact hole Ha. The first gate electrode Ha penetrates to the first gate electrode 24. The first gate electrode 24 is connected to the first connection line 40ca via the first contact hole Ha.

In the first gate insulating film 23 and interlayer insulating film 35 is a pair of second contact holes Hb formed for each first TFT 50A. The first gate insulating film 23 and first interlayer insulating film 26 constitute a stacked insulating film 36 provided so as to cover the first semiconductor layer 22. The stacked insulating film 36 is an example insulating film. Some of the second contact holes Hb are formed in the stacked insulating film 36. The pair of second contact holes Hb penetrates to the mutually different conductor regions 22b of a corresponding one of the first semiconductor layers 22.

The first terminal electrode 37 and the second terminal electrode 38 are spaced from each other. The first terminal electrode 37 and the second terminal electrode 38 are each provided on the first interlayer insulating film 26 or second interlayer insulating film 34. The first terminal electrode 37 and the second terminal electrode 38 are connected to the conductor regions 22b of the first semiconductor layer 22 via the mutually different second contact holes Hb.

The second TFTs 50B are formed as top-gate TFTs having a bottom-contact structure. The second TFTs 50B each have a third terminal electrode 28, a fourth terminal electrode 29, a second semiconductor layer 31, a second gate insulating film 32, and a second gate electrode 33. The second semiconductor layer 31 is an example semiconductor layer.

The third terminal electrode 28 and the fourth terminal electrode 29 are spaced from each other on the first interlayer insulating film 26. The second interlayer insulating film 34 includes a third contact hole Hc formed in correspondence with any one of the second TFTs 50B. The third contact hole Hc penetrates to the third terminal electrode 28 in a predetermined one of the second TFTs 50B.

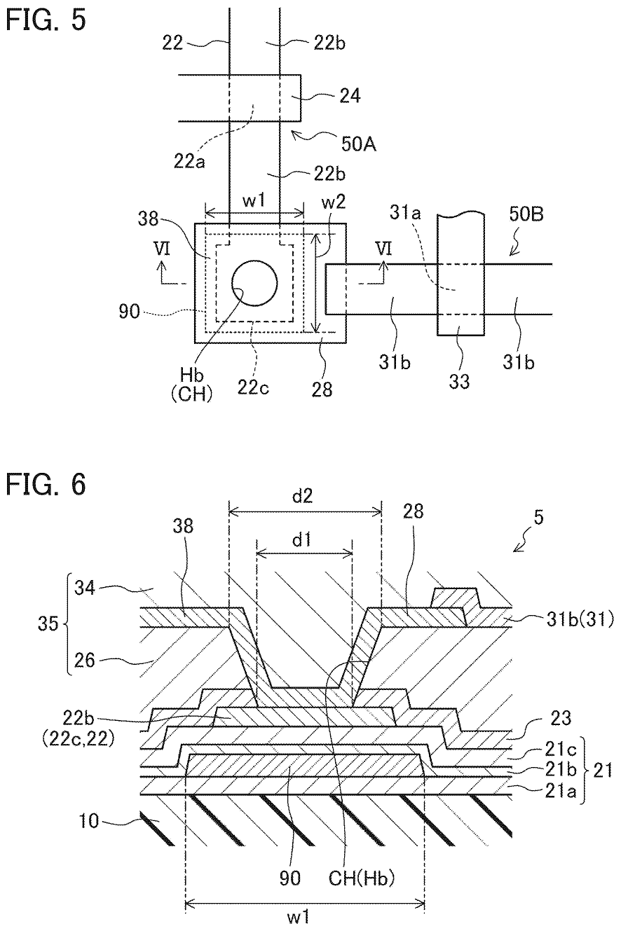

The third terminal electrode 28 in the predetermined second TFT 50B is connected, via the third contact hole Hc, to the second connection line 40cb provided on the second interlayer insulating film 34. As illustrated in FIG. 5, this third terminal electrode 28 is formed integrally with the second terminal electrode 38 in a predetermined one of the first TFTs 50A and connected to the conductor regions 22b (connecting portion 22c) of the first semiconductor layer 22 via the second contact hole Hb.

The first interlayer insulating film 26 includes a fourth contact hole Hd formed so as to correspond to any one of the second TFTs 50B; in addition, the interlayer insulating film 35 includes a fifth contact hole He formed so as to correspond to any one of the second TFTs 50B; in addition, on the first gate insulating film 23 is the relay line 40r formed so as to correspond to any one of the second TFTs 50B. The fourth contact hole Hd and the fifth contact hole He penetrate to mutually different portions of the relay line 40r.

The fourth terminal electrode 29 in the predetermined second TFT 50B is connected to the relay line 40r via the fourth contact hole Hd. The relay line 40r is connected, via the fifth contact hole He, to the third connection line 40cc provided on the second interlayer insulating film 34. Further, each of the third terminal electrode 28 and fourth terminal electrode 29 of one of the second TFTs 50B may be formed in continuity with the third terminal electrode 28 or fourth terminal electrode 29 of another one of the second TFTs 50B.

The second semiconductor layer 31 is provided in the form of an island on the first interlayer insulating film 26 and separated individually for each second TFT 50B. The second semiconductor layer 31 may be formed in continuity in the plurality of second TFTs 50B. The second semiconductor layer 31 includes a channel region 31a and a pair of conductor regions 31b. The channel region 31a is provided between the pair of conductor regions 31b. The pair of conductor regions 31b is spaced from each other with the channel region 31a interposed therebetween.

One of the conductor regions 31b of the second semiconductor layer 31 partially overlaps the third terminal electrode 28, and the other conductor region 31b partially overlaps the fourth terminal electrode 29. The second semiconductor layer 31 is thus connected to the conductor regions 22b of the first semiconductor layer 22 via the second contact hole Hb (contact hole CH). The second semiconductor layer 31 is also connected to the relay line 40r via the fourth contact hole Hd, and to the third connection line 40cc via the relay line 40r and fifth contact hole He.

The second gate insulating film 32 is provided in the form of an island on the second semiconductor layer 31 and individually separated for each second TFT 50B. The second gate insulating film 32 may cover a plurality of second semiconductor layers 31 and be provided in continuity in the plurality of second TFTs 50B. The second gate electrode 33 is provided on the second gate insulating film 32.

The second gate electrode 33 overlaps the channel region 31a of the second semiconductor layer 31 via the second gate insulating film 32. The second interlayer insulating film 34 includes a sixth contact hole Hf formed in correspondence with any one of the second TFTs 50B. The sixth contact hole Hf penetrates to the second gate electrode 33. The second gate electrode 33 is connected to the fourth connection line 40cd via the sixth contact hole Hf.

The capacitor 55 includes the first capacitive electrode 25, a second capacitive electrode 30, and the first interlayer insulating film 26. The first capacitive electrode 25 is provided on the first gate insulating film 23. The second capacitive electrode 30 is provided on the first interlayer insulating film 26. The first capacitive electrode 25 and the second capacitive electrode 30 overlap each other with the first interlayer insulating film 26 interposed therebetween.

The first gate insulating film 23, the first interlayer insulating film 26, the second gate insulating film 32, and the second interlayer insulating film 34 contain an inorganic insulating material, such as silicon oxide, silicon nitride, and silicon oxynitride. These various inorganic insulating films may be formed from a monolayer film or a multilayer film.

The foregoing various wiring lines and electrodes contain a metal material, such as aluminum (Al), tungsten (W), molybdenum (Mo), tantalum (Ta), chromium (Cr), titanium (Ti), or copper (Cu). These various wiring lines and electrodes may be formed from a monolayer film or a multilayer film.

The first semiconductor layer 22 contains polysilicon. The polysilicon contained in the first semiconductor layer 22 is low-temperature polycrystalline silicon (LTPS) for instance. The second semiconductor layer 31 contains an oxide semiconductor. The oxide semiconductor contained in the second semiconductor layer 31 is an In—Ga—Zn—O semiconductor for instance.

The In—Ga—Zn—O semiconductor is a ternary oxide of indium (In), gallium (Ga), and zinc (Zn) and may contain In, Ga, and Zn at any ratio (composition ratio). The In—Ga—Zn—O semiconductor may be amorphous or crystalline. Further, the second semiconductor layer may contain other kinds of oxide semiconductor in addition to or instead of an In—Ga—Zn—O semiconductor.

The other kinds of oxide semiconductor may include an In—Sn—Zn—O semiconductor (e.g., In₂O₃—SnO₂—ZnO, InSnZnO) for instance. Here, the In—Sn—Zn—O semiconductor is a ternary oxide of indium (In), tin (Sn), and zinc (Zn).

Further, the other kinds of oxide semiconductor may include an In—Al—Zn—O semiconductor, an In—Al—Sn—O semiconductor, a Zn—O semiconductor, an In—Zn—O semiconductor, a Zn—Ti—O semiconductor, a Cd—Ge—O semiconductor, a Cd—Pb—O semiconductor, cadmium oxide (CdO), a Mg—Zn—O semiconductor, and an In—Ga—Sn—O semiconductor.

Further, the other kinds of oxide semiconductor may include, but not limited to, an In—Ga—O semiconductor, a Zr—In—Zn—O semiconductor, a Hf—In—Zn—O semiconductor, an Al—Ga—Zn—O semiconductor, InGaO₃(ZnO)₅, magnesium zinc oxide (MgₓZn₁₋ₓO), and cadmium zinc oxide (CdₓZn₁₋ₓO).

The flattening film 58 is provided over the second interlayer insulating film 34 so as to cover the various wiring lines 40, the plurality of TFTs 50, and the plurality of capacitors 55 in the display region DA. The flattening film 58 extends all over the display region DA. The flattening film 58 flattens the surface of the TFT layer 20.

The flattening film 58 includes a seventh contact hole Ha formed for each subpixel SP. The seventh contact hole Hg penetrates to the second connection line 40cb. The flattening film 58 contains, but not limited to, an organic resin material, such as polyimide resin or acrylic resin, or a polysiloxane spin-on-glass (SOG) material.

The first to seventh contact holes Ha, Hb, Hc, Hd, He, Hf, and Hg are each provided in correspondence with the plurality of subpixels SP (all the subpixels SP) constituting the display region DA. Hereinafter, the second contact hole Hb connecting the third terminal electrode 28 to the first semiconductor layer 22 is closely related to the technique of the present disclosure and will be thus also simply referred to as a “contact hole CH” for convenience.

### Light-Emitting Element Layer

The light-emitting element layer 60 is provided on the TFT layer 20. The light-emitting element layer 60 includes the plurality of organic EL elements (organic electroluminescence elements) 65 and an edge cover 66. The organic EL elements 65 are example light-emitting elements. The organic EL elements 65 are top-emission elements. Light emitted from the organic EL elements 65 is extracted toward the sealing film 80.

The plurality of organic EL elements 65 is provided in one-to-one correspondence with the plurality of subpixels SP. Each organic EL element 65 constitutes the subpixel SP. The emission of each organic EL element 65 is controlled by the operation of a corresponding one of the pixel circuits PC. Each organic EL element 65 has the pixel electrode 61, an organic EL layer 62, and a common electrode 63.

The pixel electrodes 61 are provided on the flattening film 58. The pixel electrodes 61 are arranged in matrix in one-to-one correspondence with the plurality of subpixels. Each pixel electrode 61 is connected to the second connection line 40cd via the seventh contact hole Hg. The pixel electrode 61 functions as an anode and injects positive holes (holes) into the organic EL layer 62. It is preferable for the pixel electrode 61 to contain a conductive material having a large work function.

The pixel electrode 61 is made of metal, such as silver (Ag), aluminum (Al), nickel (Ni), titanium (Ti), indium (In), or tin (Sn). The pixel electrode 61 may be made of a metal compound, or alloy. The pixel electrode 61 may be made of conductive oxide, such as indium tin oxide (ITO) or indium zinc oxide (IZO). The pixel electrode 61 may be formed from a monolayer film or a multilayer film.

The edge cover 66 is provided on the flattening film 58. The edge cover 66 is located above the pixel electrode 61. The edge cover 66 is formed in a lattice shape so as to partition the plurality of pixel electrodes 61. To be specific, the edge cover 66 extends between the pixel electrodes 61 adjacent to each other and around the display region DA, and the edge cover 66 covers the outer edges (perimeters) of the individual pixel electrodes 61.

The edge cover 66 has a plurality of openings 67 corresponding to the subpixels SP. Each opening 67 partially exposes the pixel electrode 61 from the edge cover 66. The edge cover 66 contains a material similar to that of the flattening film 58; for instance, the edge cover 66 contains an organic resin material, such as polyimide resin or acrylic resin, or a polysiloxane SOG material.

The organic EL layer 62 is provided on the individual pixel electrode 61 within the opening 67 of the edge cover 66. The organic EL layer 62 has a hole injection layer, a hole transport layer, an emission layer, an electron transport layer, and an electron injection layer. The hole injection layer, the hole transport layer, the emission layer, the electron transport layer, and the electron injection layer are stacked on the pixel electrode 61 in the stated order and contain a publicly known compound suitable for each of their functions. The organic EL layer 62 emits light by applying current between the pixel electrode 61 and the common electrode 63.

The common electrode 63 is provided as a continuous film shared among the plurality of subpixels SP so as to extend all over the display region DA. The common electrode 63 covers the edge cover 66 and each organic EL layer 62, and the common electrode 63 overlaps each pixel electrode 61 with the organic EL layer 62 interposed therebetween. The common electrode 63 extends also to the frame region FA and is connected to the second frame line 40b. The common electrode 63 functions as a cathode and injects electrons into the organic EL layers 62. It is preferable for the common electrode 63 to contain a conductive material having a small work function.

The common electrode 63 is made of conductive oxide, such as indium zinc oxide (ITO) or indium zinc oxide (IZO). The common electrode 63 may be made of metal, such as silver (Ag), aluminum (Al), lithium (Li), magnesium (Mg), calcium (Ca), or ytterbium (Yb). The common electrode 63 may be made of a metal compound, or alloy. The common electrode 63 may be formed from a monolayer film or a multilayer film.

### Sealing Film

The sealing film 80 is provided on the light-emitting element layer 60. The sealing film 80 covers and seals the plurality of organic EL elements 65 to protect each organic EL element 65 (in particular, each organic EL layer 62) from moisture, oxygen, and other things. The sealing film 80 is provided all over the display region DA and extends to the frame region FA. The sealing film 80 has a first inorganic sealing layer 81, an organic sealing layer 82, and a second inorganic sealing layer 83.

The first inorganic sealing layer 81, the organic sealing layer 82, and the second inorganic sealing layer 83 are provided on the light-emitting element layer 60 in the stated order. The first inorganic sealing layer 81 and the second inorganic sealing layer 83 extend further to the outer periphery of the frame region FA than the organic sealing layer 82, and they overlap each other outside the frame region FA. The organic sealing layer 82 is wrapped around by the first inorganic sealing layer 81 and the second inorganic sealing layer 83.

The first inorganic sealing layer 81 and the second inorganic sealing layer 83 each contain an inorganic insulating material, such as silicon oxide, silicon nitride, or silicon oxynitride. The organic sealing layer 82 contains an organic resin material, such as acrylic resin, epoxy resin, silicone resin, polyurea resin, parylene resin, polyimide resin, or polyamide resin. The organic sealing layer 82 is formed by applying a liquid material.

### Countermeasure Against Moisture Intrusion Into Second Semiconductor Layer

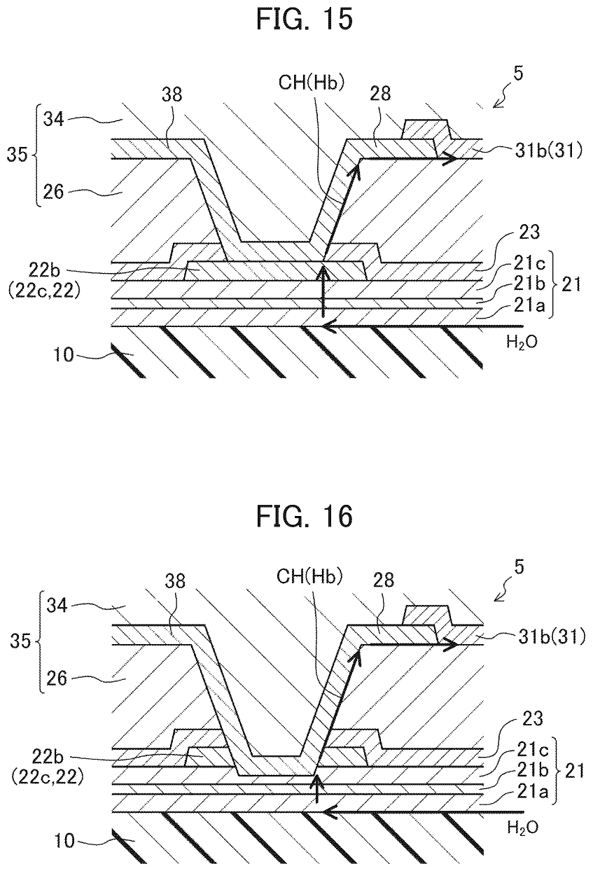

As illustrated in FIG. 15, the circuit board 5 according to a comparative example is susceptible to intrusion of external moisture (H₂O) from the end face of the circuit board 5 through the interface between the substrate layer 10 and base coat film 21. The moisture propagated through the interface between the substrate layer 10 and base coat film 21 transmits through the base coat film 21 and first semiconductor layer 22 directly under the contact hole CH and further intrudes into the upper layer of the first interlayer insulating film 26 via the contact hole CH. Then, upon reaching the second semiconductor layer 31, the moisture intruded into the upper layer of the first interlayer insulating film 26 changes the property of the second semiconductor layer 31.

Accordingly, the property of the second TFT 50B shifts, causing variations in the property of the second TFTs 50B in the respective pixel circuits PC. This produces unevenness in an image display of the organic EL display 1. In particular, when the contact hole CH penetrates the first semiconductor layer 22 to reach the base coat film 21, as illustrated in FIG. 16, due to variations in the depth of the finished contact holes CH, so that the second terminal electrode 38 is annularly connected to the first semiconductor layer 22, the foregoing moisture intrusion prominently causes a property change in the second semiconductor layer 31.

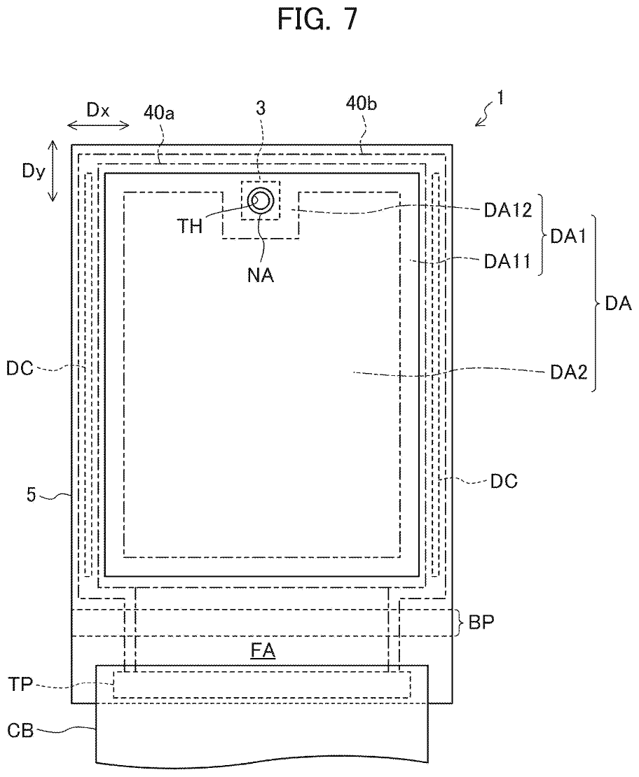

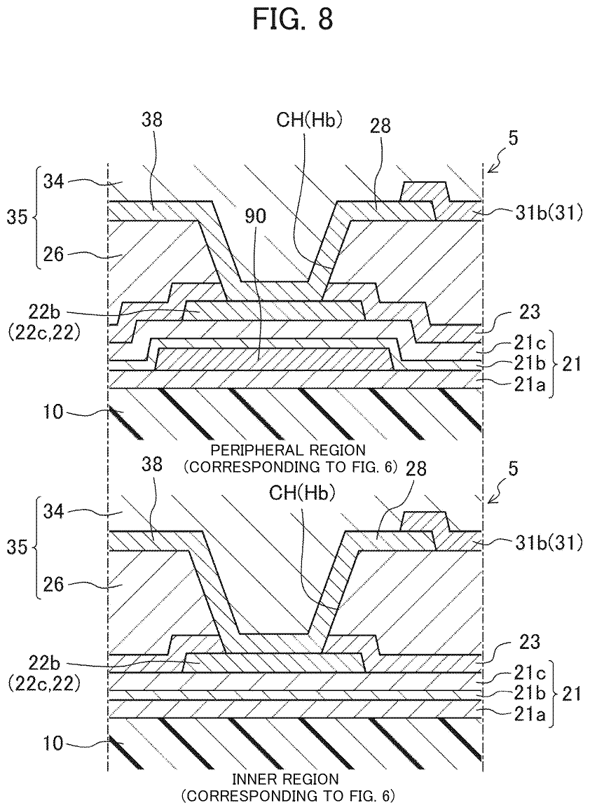

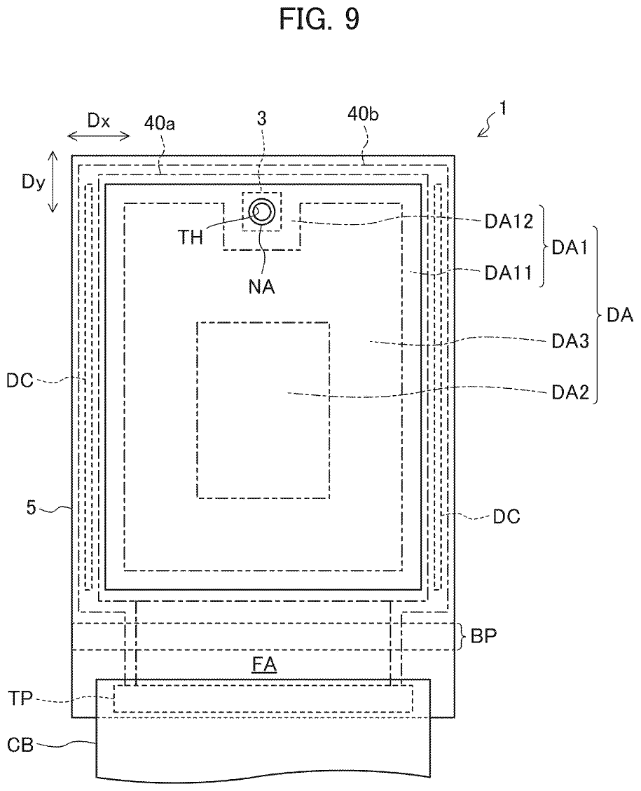

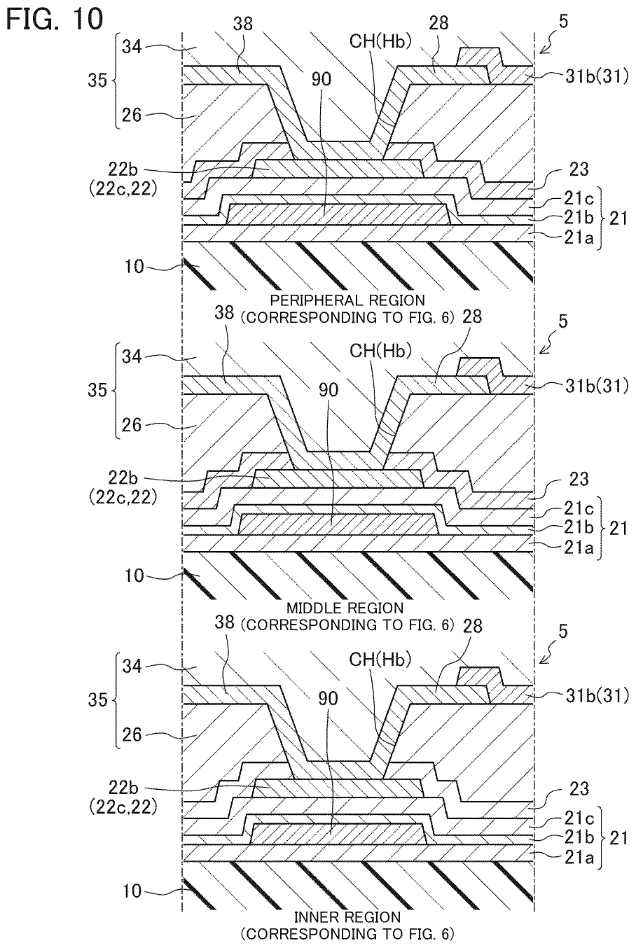

To address this, the circuit board 5 according to the first embodiment includes a plurality of intervening layers 90, as illustrated in FIGS. 4 to 6, in order to prevent the moisture propagated through the interface between the substrate layer 10 and base coat film 21 from reaching the second semiconductor layer 31. The plurality of intervening layers 90 are each formed in a rectangular island shape. The shape of each intervening layer 90 may be an island shape other than a rectangular, such as a circle. Moreover, the intervening layers 90 are provided individually in correspondence with the plurality of subpixels SP. The intervening layers 90 in this example are provided in all the subpixels SP.

Each intervening layer 90 is interposed between the substrate layer 10 and the first semiconductor layer 22 in a region corresponding to the contact hole CH. The contact hole CH is formed such that its opening area decreases downward, and the contact hole CH has a tapered inner peripheral surface 36a. Each intervening layer 90 is provided between the inorganic insulating films constituting the base coat film 21. The intervening layer 90 in this embodiment is provided between the first inorganic insulating film 21a and the second inorganic insulating film 21b.

The first inorganic insulating film 21a is positioned below the intervening layer 90. The second inorganic insulating film 21b and the third inorganic insulating film 21c are positioned above the intervening layer 90. As described above, the inorganic insulating films constituting the base coat film 21 include one layer below the intervening layer 90, and a plurality of layers (two layers) above the intervening layer 90. The intervening layer 90 may be provided between the second inorganic insulating film 21b and the third inorganic insulating film 21c.

Each intervening layer 90 is provided so as to overlap, in plan view, the entire opening in the lower part of the contact hole CH. Widths w1 and w2 along the individual sides of the intervening layer 90 (in the intervening layer 90 that is circular, the diameter) are larger than an opening diameter d1 in the lower part of the contact hole CH. Moreover, each intervening layer 90 is preferably provided so as to overlap, in plan view, the entire opening in the upper part of the contact hole CH. In this case, the widths w1 and w2 along the individual sides of the intervening layer 90 (in the intervening layer 90 that is circular, the diameter) are larger than an opening diameter d2 in the upper part of the contact hole CH. Furthermore, each intervening layer 90 is further preferably provided so as to overlap, in plan view, the entire connecting portion 22c of the first semiconductor layer 22, to which the second terminal electrode 38 is connected via the contact hole CH.

The intervening layers 90 is formed from an inorganic insulating material or a metal material. An example of the inorganic insulating material of the intervening layers 90 is silicon nitride (SiN). Examples of the metal material of the intervening layer 90 include molybdenum (Mo), aluminum (Al), tungsten (W), tantalum (Ta), chromium (Cr), titanium (Ti), and copper (Cu). The material of the intervening layers 90 is preferably a moisture-impervious material.

### Method for Manufacturing Organic EL Display

To manufacture the organic EL display 1, the first process step is applying an organic resin material onto the surface of a glass substrate, followed by baking. This forms the substrate layer 10 on the glass substrate.

The next is forming the TFT layer 20, the light-emitting element layer 60, and the sealing film 80 in the stated order through publicly known film formation, such as plasma chemical vapor deposition (CVD), sputtering, or vacuum evaporation, through publicly known application, such as spin coating or slit coating, and through publicly known patterning, such as photolithography. In the step of forming the TFT layer 20, the intervening layers 90 may be formed onto the first inorganic insulating film 21a after the formation of the first inorganic insulating film 21a of the base coat film 21, and before the formation of the second inorganic insulating film 21b of the same.

The next is removing the glass substrate, 100, from the substrate layer 10 through, for instance, laser light irradiation from the glass substrate 100 to the back surface of the substrate layer 10. The next is attaching a protective film onto the back surface of the substrate layer 10. In addition, a polarizer plate and a cover panel are attached onto the surface of the sealing film 80. Furthermore, the wiring board CB is connected to the terminal section TP. Accordingly, a display control circuit (source driver) is mounted on a panel constituting the organic EL display 1.

The organic EL display 1 can be manufactured through the foregoing process steps.

### Features in First Embodiment

The circuit board 5 according to the first embodiment includes the island-shaped intervening layer 90 between the substrate 10 and the first semiconductor layer 22 in a region corresponding to the contact hole CH. The intervening layer 90 inhibits the moisture propagated through the interface between the substrate layer 10 and base coat film 21 from permeating the contact hole CH. This can prevent the moisture from reaching the second semiconductor layer 31 from the substrate layer 10 through the contact hole CH. This can prevent the second semiconductor layer 31 from a property change resulting from moisture intrusion.

Moreover, the circuit board 5 according to the first embodiment, which includes the island-shaped intervening layer 90, can reduce an internal stress resulting from providing the intervening layer 90. This offers the intervening layer 90 that is relatively thick, thereby facilitating enhancement of moisture-permeation avoidance. Furthermore, the intervening layer 90 that is formed from an inorganic insulating material can prevent a crack resulting from a bending of the circuit board 5 or other factors. In addition, the intervening layer 90 that is formed from a metal material can reduce influences of electrification resulting from the intervening layer 90, and of light reflection of the intervening layer 90 upon an image display.

The base coat film 21 in the circuit board 5 according to the first embodiment has a stack of inorganic insulating films. This base coat film 21 has a relatively high anti-moisture function of preventing moisture permeation when compared to a monolayer base coat film. Moreover, the intervening layer 90 is provided between the inorganic insulating films constituting the base coat film 21. This can suitably prevent the moisture propagated through the interface between the substrate layer 10 and base coat film 21 from permeating the contact hole CH.

In the circuit board 5 according to the first embodiment, the intervening layer 90 is provided so as to overlap, in plan view, the entire opening in the lower part of the contact hole CH. The intervening layer 90 can thus more completely block the shortest path through which the moisture propagated through the interface between the substrate layer 10 and intervening layer 21 intrude into the contact hole CH. This is advantageous for preventing the moisture from reaching the second semiconductor layer 31 from the substrate layer 10 through the contact hole CH.

In the circuit board 5 according to the first embodiment, the intervening layer 90 is provided so as to overlap, in plan view, the entire opening in the upper part of the contact hole CH. Accordingly, the tapered shape of the inner peripheral surface of the contact hole CH can be prevented from a deformation caused by a level difference formed by the intervening layer 90. This is advantageous for favorably connecting the second terminal electrode 38 as well as the third terminal electrode 28 and the first semiconductor layer 22 together, and by extension, the second semiconductor layer 31 and the first semiconductor layer 22 together.

The organic EL display 1 according to the first embodiment includes the circuit board 5. This can prevent the second semiconductor layer 31 from a property change, so that the organic EL display 1 can have favorable display quality and enhanced reliability.

In the organic EL display 1 according to the first embodiment, the intervening layers 90 are provided individually in correspondence with the plurality of subpixels SP. Providing the intervening layers 90 as a minute pattern like this can suitably prevent an internal stress resulting from providing the intervening layers 90. This is advantageous for adjusting the thickness of the intervening layers 90 to a range within which moisture permeation can be effectively prevented. Further, the second semiconductor layer 31 constitutes the second TFT 50B provided in each subpixel SP. Providing the intervening layers 90 can prevent the second TFTs 50B from a property change resulting from moisture intrusion.

In the organic EL display 1 according to the first embodiment, the intervening layers 90 are provided in all the subpixels SP. This enables the property of the second TFTs 50B in all the subpixels SP to be uniformly prevented from a change resulting from moisture intrusion.

### Second Embodiment

The organic EL display 1 according to a second embodiment is different from that according to the first embodiment in the range of placement of the intervening layers 90. It is noted that the organic EL display 1 according to the following embodiments has a configuration similar to that according to the first embodiment with the exception that the range of placement of the intervening layers 90 is different from that according to the first embodiment; accordingly, the detailed description of the organic EL display 1 will not be described.

In the organic EL display 1 according to the second embodiment, the intervening layers 90 are provided only in some of the subpixels SP in the display region DA. As illustrated in FIG. 7, the display region DA has a peripheral region DA1 and an inner region DA2. The peripheral region DA1 in this example includes an outer peripheral region DA11 and an inner peripheral region DA12. The outer peripheral region DA11 is a region along the outer periphery of the display area DA. The inner peripheral region DA12 is a region along the periphery of the through-hole TH in the display region DA.

The peripheral region DA1 is a frame-shaped region along the edge of the substrate layer 10 and has a relatively large amount of moisture that intrudes from outside into the interface between the substrate layer 10 and base coat film 21. Thus, in each subpixel SP in the peripheral region DA1, the property of the second semiconductor layer 31 is susceptible to a change resulting from moisture intrusion. Accordingly, the intervening layers 90 are provided in the plurality of subpixels SP constituting the peripheral region DA1 (the outer peripheral region DA11 and the inner peripheral region DA12), as illustrated in the upper part of FIG. 8.

The inner region DA2 is a region excluding the peripheral region DA1 and has a relatively small amount of moisture that intrudes from outside into the interface between the substrate layer 10 and base coat film 21. Thus, the second semiconductor layer 31 located in each subpixel SP in the inner region DA2 is less susceptible to a property change resulting from moisture intrusion than the first semiconductor layer 22 located in each subpixel SP in the peripheral region DA1. Accordingly, the intervening layers 90 are not provided in the plurality of subpixels SP constituting the inner region DA2, as illustrated in the lower part of FIG. 8.

### Features in Second Embodiment

In the organic EL display 1 according to the second embodiment, the intervening layers 90 are provided in the plurality of subpixels SP constituting the peripheral region DA1 of the display region DA. The intervening layer 90 provided in each subpixel SP in the peripheral region DA1 effectively functions to prevent a property change in the second semiconductor layer 31. On the other hand, the intervening layers 90 are not provided in the inner region DA2 of the display region DA. Accordingly, the degree of a property change in the second semiconductor layer 31 resulting from moisture intrusion can be balanced between the peripheral region DA1 and the inner region DA2. This is advantageous for preventing unevenness in an image display of the organic EL display 1.

### Third Embodiment

In the organic EL display 1 according to a third embodiment, the size (area in plan view) of the intervening layers 90 is different among a plurality of regions divided from the display region DA. As illustrated in FIG. 9, the display region DA has the peripheral region DA1, a middle region DA3, and the inner region DA2. The peripheral region DA1 is a region similar to that in the second embodiment. The middle region DA3 is a frame-shaped region along the inner periphery of the peripheral region DA1. The inner region DA2 is a region located inside the middle region DA3.

As illustrated in FIG. 10, the intervening layers 90 are provided in the plurality of subpixels SP constituting the peripheral region DA1, the plurality of subpixels SP constituting the middle region DA3, and the plurality of subpixels SP constituting the inner region DA2. When the moisture propagated from outside through the interface between the base coat film 10 and base coat film 21 reaches the second semiconductor layer 31, the property of the second semiconductor layer 31 shifts in accordance with the amount of moisture. The amount of moisture that reaches the second semiconductor layer 31 increases along with approach to the end face of the substrate layer 10, and it decreases along with distance from the end face of the substrate layer 10.

As such, the size of the intervening layers 90 decreases in the order of the peripheral region DA1, the middle region DA3, and the inner region DA2. That is, the intervening layer 90 provided in the peripheral region DA1 is larger than the intervening layer 90 provided in the middle region DA3. The intervening layer 90 provided in the middle region DA3 is larger than the intervening layer 90 provided in the inner region DA2. For instance, the intervening layer 90 in the inner region DA2 is set to have a size equal to the size of the connecting portion 22c of the first semiconductor layer 22.

### Features in Third Embodiment

In the organic EL display 1 according to the third embodiment, the size of the intervening layers 90 decreases in the order of the peripheral region DA1, the middle region DA3, and the inner region DA2. Accordingly, the degree of a property change in the second semiconductor layer 31 resulting from moisture intrusion can be balanced between the peripheral region DA1, the middle region DA3, and the inner region DA2 by adjusting the amount of moisture that reaches the second semiconductor layer 31 from outside through the interface between the substrate layer 10 and base coat film 21 so as to be balanced between these regions. This is advantageous for preventing unevenness in an image display of the organic EL display 1.

### Modifications

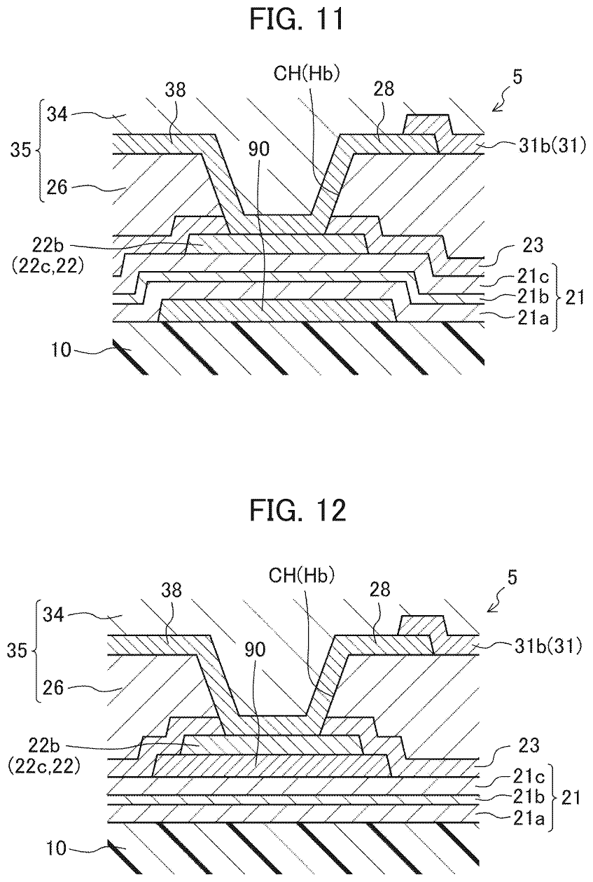

The intervening layer 90 may be provided between the substrate layer 10 and the base coat film 21, as illustrated in FIG. 11. Alternatively, the intervening layer 90 may be provided above the base coat film 21, as illustrated in FIG. 12. In this case, the connecting portion 22c of the first semiconductor layer 22 is provided immediately above the intervening layer 90. In short, the intervening layer 90 is preferably provided in a region corresponding to the contact hole CH so as to be interposed between the substrate layer 10 and the connecting portion 22c of the first semiconductor layer 22.

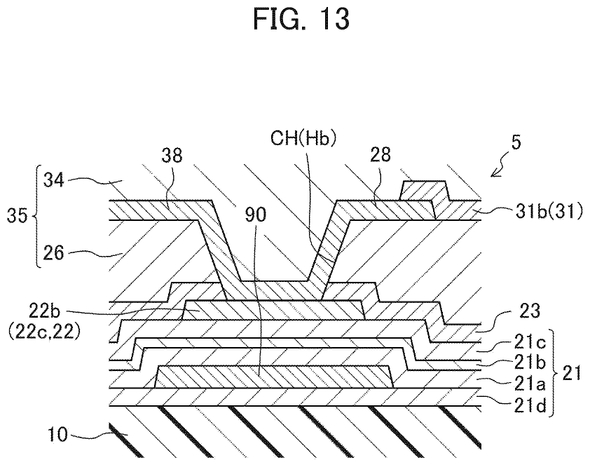

As illustrated in FIG. 13, the base coat film 21 may have a four-ply structure. The base coat film 21 in this case has a fourth inorganic insulating film 21d in addition to the first to third inorganic insulating films 21a, 21b, and 21c. The fourth inorganic insulating film 21d is located in the lowest layer of the plurality of inorganic insulating films constituting the base coat film 21. That is, the fourth inorganic insulating film 21d is provided below the first inorganic insulating film 21a. Moreover, the intervening layer 90 may be provided between the fourth inorganic insulating film 21d and the first inorganic insulating film 21a. In this case as well, a plurality of inorganic insulating films (three layers) constituting the base coat film 21 is provided above the intervening layer 90.

### Other Embodiments

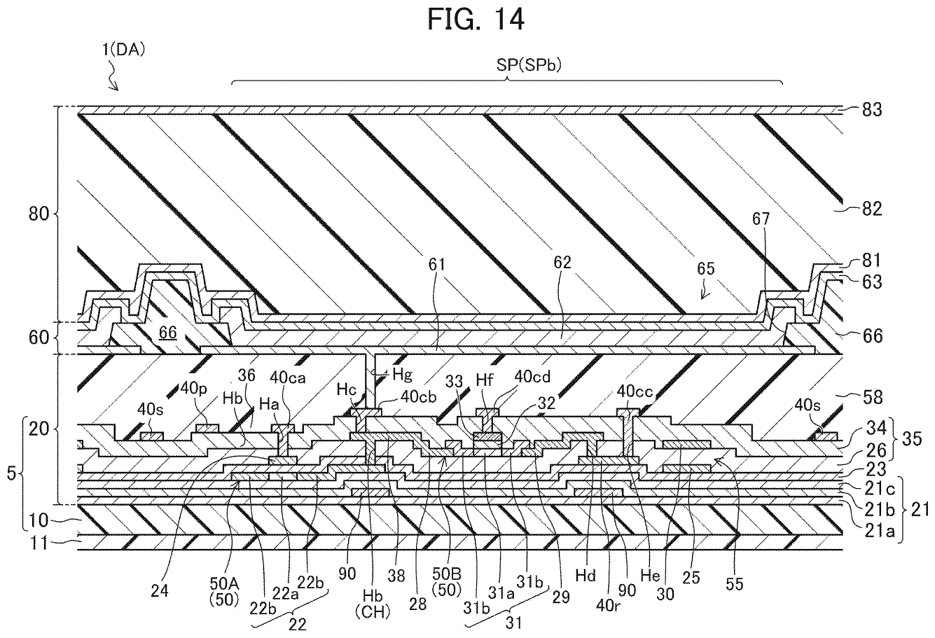

The first to three embodiments have described, by way of example, aspects in which the intervening layer 90 is provided only in a region corresponding to the contact hole CH (second contact hole Hb), via which the third terminal electrode 28 of the second TFT 50B is connected to the first semiconductor layer 22. As illustrated in FIG. 14, the intervening layer 90 may be provided also in a region corresponding to the fourth contact hole Hd, via which the fourth terminal electrode 29 of the second TFT 50B is connected to the relay line 40r. This can prevent the moisture propagated through the interface between the substrate layer 10 and base coat film 21 from permeating the fourth contact hole Hd, and from reaching the second semiconductor layer 31 from the substrate layer 10 through the fourth contact hole Hd.

The first to third embodiments have described, by way of example, aspects in which the third terminal electrode 28 of the second TFT 50B is formed integrally with the second terminal electrode 38 of the first TFT 50A to be connected to the first semiconductor layer 22. The conductive portion according to the technique of the present disclosure is not limited to a semiconductor layer; it may be a wiring line or an electrode. For instance, the third terminal electrode 28 of the second TFT 50B may be connected to a metal wiring line via the contact hole CH. This metal wiring line may be formed integrally with the second terminal electrode 38 of the first TFT 50A to be connected to the first semiconductor layer 22.

The first to third embodiments have described, by way of example, that the organic EL layer 62 is individually provided in each subpixel SP. The organic EL layer 62 may be shared among the plurality of subpixels SP as a single continuous layer. In this case, the organic EL display 1 may include a color filter for color tone expression in each subpixel SP.

The first to third embodiments have described, by way of example, that each pixel PX includes the subpixels SP of three colors. The subpixels SP of four or more colors may constitute each pixel PX. Further, the embodiments have described, by way of example, that the subpixels SP of three colors constituting each pixel PX are arranged in a stripe manner. The arrangement of the plurality of subpixels SP may be another arrangement, such as a PenTile matrix.

The first to third embodiments have described, by way of example, that the pixel electrode 61 functions as an anode, and that the common electrode 63 functions as a cathode. The organic EL display 1 may be configured such that the pixel electrode 61 functions as a cathode, and that the common electrode 63 functions as an anode. In this case, the organic EL layer 62 has an inverted stacked structure.

The first to third embodiments have described, by way of example, that the organic EL layer 62 has a five-ply structure composed of a hole injection layer, a hole transport layer, an emission layer, an electron transport layer, and an electron injection layer. The organic EL layer 62 may have a three-ply structure composed of a hole injection-and-transport layer, an emission layer, and an electron transport-and-injection layer; alternatively, the organic EL layer 62 can have any other stacked structure.

The first to third embodiments have described, by way of example, that the substrate of the organic EL display 1 is the substrate layer 10. The substrate can be one containing any light-transparent material, such as a plastic substrate containing polyethylene terephthalate (PET), or a glass substrate.

The first to third embodiments have described, by way of example, the camera 3 as an electronic component combined with the organic EL display 1. The electronic component may be another electronic component, such as a fingerprint sensor, a face authentication sensor, or a luminance sensor, that is disposed on the backside of the organic EL display 1, and that uses light passed through the through-hole TH. Further, the organic EL display 1 does not have to have the through-hole TH and to be combined with an electronic component, such as a camera, that uses light.

The first to third embodiments have described, by way of example, the organic EL display 1 as a display device according to the present disclosure. The technique of the present disclosure is applicable to a display device including a plurality of light-emitting elements. An example of the display device is a quantum-dot display device including quantum-dot light-emitting diodes, which are light-emitting elements including a quantum-dot containing layer. Other than the foregoing, the technique of the present disclosure is also applicable to a liquid crystal display and a plasma display.

As described above, preferred embodiments have been described as examples of the technique of the present disclosure. However, the technique of the present disclosure is not limited to these preferred embodiments; it is also applicable to embodiments in which changes, replacements, additions, and omissions are made as appropriate. It is understood by those skilled in the art that the above embodiments can be further modified in various manners without departing from the spirit of the technique of the present disclosure, and that such modifications also fall within the scope of the technique of the present disclosure.

### INDUSTRIAL APPLICABILITY

As described above, the technique of the present disclosure is useful for a circuit board, and a display device provided with the same.

1. A circuit board comprising:
a substrate;
a base coat film provided on the substrate;
a conductive portion provided on the base coat film;
an insulating film provided so as to cover the conductive portion; and
a semiconductor layer provided on the insulating film and containing an oxide semiconductor,
the insulating film including a contact hole penetrating to the conductive portion,
the semiconductor layer being electrically connected to the conductive portion via the contact hole,
the circuit board further comprising an intervening layer having an island shape, and interposed between the substrate and the conductive portion in a region corresponding to the contact hole.

2. The circuit board according to claim 1, wherein
the base coat film is formed by stacking a plurality of inorganic insulating films, and
the intervening layer is provided between the plurality of inorganic insulating films.

3. The circuit board according to claim 2, wherein the plurality of inorganic insulating films is provided above the intervening layer.

4. The circuit board according to claim 1, wherein the intervening layer is provided so as to overlap, in a plan view, an entire opening in a lower part of the contact hole.

5. The circuit board according to claim 4, wherein
the contact hole is formed such that an opening area of the contact hole decreases downward, and the contact hole has a tapered inner peripheral surface, and
the intervening layer is provided so as to overlap, in the plan view, an entire opening in an upper part of the contact hole.

6. The circuit board according to claim 1, wherein the intervening layer is formed from an inorganic insulating material.

7. The circuit board according to claim 1, wherein the intervening layer is formed from a metal material.

8. The circuit board according to claim 1, comprising:
a first thin-film transistor having a first semiconductor layer containing polysilicon; and
a second thin-film transistor having a second semiconductor layer that is the semiconductor layer,
wherein a part of the first semiconductor layer constitutes the conductive portion.

9. The circuit board according to claim 1, wherein the substrate is a flexible resin substrate.

10. A display device comprising the circuit board according to claim 1.

11. The display device according to claim 10, wherein
the conductive portion, the semiconductor layer, and the contact hole are provided in correspondence with a plurality of subpixels constituting a display region, and
the intervening layer is provided individually in correspondence with the plurality of subpixels.

12. The display device according to claim 11, wherein the intervening layer is provided in all the plurality of subpixels constituting the display region.

13. The display device according to claim 11, wherein
the display region has
a peripheral region along an edge of the substrate, and
an inner region excluding the peripheral region, and
the intervening layer is provided in the plurality of subpixels constituting the peripheral region, but is not provided in the plurality of subpixels constituting the inner region.

14. The display device according to claim 13, wherein the peripheral region includes an outer peripheral region along a periphery of the display region.

15. The display device according to claim 13, wherein
a non-display region having an island shape is provided inside the display region,
a through-hole penetrating in a thickness direction of the circuit board is formed in the non-display region, and
the peripheral region includes an inner peripheral region along a periphery of the through-hole in the display region.

16. The display device according to claim 11, comprising:
a thin-film transistor layer including a thin-film transistor having the base coat film, the conductive portion, the insulating film, and the semiconductor layer; and
a light-emitting element layer provided on the thin-film transistor layer,
wherein the light-emitting element layer includes a plurality of light-emitting elements provided in correspondence with the plurality of subpixels, and
the thin-film transistor and the conductive portion constitute, for each of the plurality of subpixels, a pixel circuit configured to control emission of a corresponding one of the plurality of light-emitting elements.

17. The display device according to claim 16, wherein the plurality of light-emitting elements is organic electroluminescence elements.
